(19) United States
(12) Patent Application Publication
(10) Pub. No.: US 2025/0322890 A1
(43) Pub. Date: Oct. 16, 2025

(54) MEMORY DEVICE AND METHOD OF OPERATING THE SAME

(71) Applicant: SK hynix Inc., Icheon-si Gyeonggi-do (KR)

(72) Inventors: Jong Woo KIM, Icheon-si Gyeonggi-do (KR); Young Cheol SHIN, Icheon-si Gyeonggi-do (KR)

(73) Assignee: SK hynix Inc., Icheon-si Gyeonggi-do (KR)

(21) Appl. No.: 19/032,834

(22) Filed: Jan. 21, 2025

(30) Foreign Application Priority Data
Apr. 12, 2024 (KR) 10-2024-0049502

(51) Int. Cl. G11C 16/26; G11C 16/32; G11C 16/34

(52) U.S. Cl. CPC G11C 16/26; G11C 16/32; G11C 16/3459

(57) ABSTRACT

A memory device includes a memory cell array, a plurality of page buffers, and a sensing operation controller. The memory cell array includes a plurality of memory cells. The plurality of page buffers performs strobe operations of latching data stored in the plurality of memory cells. Strobe information storage stores split condition information regarding the start timing of the strobe operations. The sensing operation controller controls the start timing of the strobe operations according to an expected number of latch flips of a sensing latch included in each of the plurality of page buffers in a program verify operation, based on the split condition information regarding the start timing.

### CROSS-REFERENCE TO RELATED APPLICATION

The present application claims priority under 35 U.S.C. § 119 (a) to Korean patent application number 10-2024-0049502 filed on Apr. 12, 2024, in the Korean Intellectual Property Office, the entire contents of which application is incorporated herein by reference.

### BACKGROUND

### 1. Technical Field

The present disclosure relates to an electronic device, and more particularly, to a memory device and a method of operating the memory device.

### 2. Related Art

A storage device is a device that stores data under the control of a host device such as a computer or a smartphone. The storage device may include a memory device in which data is stored and a memory controller controlling the memory device. The memory device is classified as a volatile memory device or a nonvolatile memory device.

The memory device may include page buffers for sensing data stored in a memory cell. A latch included in a page buffer may perform a strobe operation of latching the sensed data. The page buffers may control the start timing of strobe operations to prevent a voltage drop and improve reliability of a sensing operation.

### SUMMARY

A memory device in accordance with an embodiment of the present disclosure may include a memory cell array, a plurality of page buffers, and a sensing operation controller. The memory cell array may include a plurality of memory cells. The plurality of page buffers may be configured to perform strobe operations of latching data stored in the plurality of memory cells. Strobe information storage may be configured to store split condition information regarding the start timing of the strobe operations. The sensing operation controller may be configured to control the start timing of the strobe operations according to an expected number of latch flips of a sensing latch included in each of the plurality of page buffers in a program verify operation, based on the split condition information regarding the start timing.

A memory device in accordance with an embodiment of the present disclosure may include a plurality of page buffers that perform strobe operations of latching data stored in a plurality of memory cells. A method in accordance with an embodiment of the present disclosure of operating such a memory device may include setting start timing of the strobe operations according to an expected number of latch flips of a sensing latch included in each of the plurality of page buffers in a program verify operation based on split condition information regarding the start timing of the strobe operations. The method may further include performing the strobe operations according to the set start timing.

### BRIEF DESCRIPTION OF THE DRAWINGS

FIG. 1 is a diagram illustrating a memory device according to an embodiment of the present disclosure.

FIG. 2 is a diagram illustrating a page buffer according to an embodiment of the present disclosure.

FIG. 3 is a timing diagram illustrating a sensing operation of a page buffer according to an embodiment of the present disclosure.

FIG. 4 is a diagram illustrating a threshold voltage distribution and a verify level for each program state.

FIG. 5 is a diagram illustrating an incremental step pulse program (ISPP) operation according to an embodiment of the present disclosure.

FIG. 6 is a diagram illustrating a split of the start timing of strobe operations according to an embodiment of the present disclosure.

FIG. 7 is a diagram illustrating an expected number of latch flips for each verify loop count for a target program state.

FIG. 8A is a diagram illustrating split condition information regarding the start timing of a strobe operation according to an embodiment of the present disclosure.

FIG. 8B is a diagram illustrating split condition information regarding the start timing of a strobe operation according to an embodiment of the present disclosure.

FIG. 9A is a diagram illustrating split condition information regarding the start timing of a strobe operation according to an embodiment of the present disclosure.

FIG. 9B is a diagram illustrating split condition information regarding the start timing of a strobe operation according to an embodiment of the present disclosure.

FIG. 10 is a flowchart illustrating the operation of a memory device according to an embodiment of the present disclosure.

### DETAILED DESCRIPTION

Specific structural or functional descriptions of embodiments disclosed in the present specification or application are illustrated only to describe the concept of the present disclosure. Embodiments according to the concept of the present disclosure may be carried out in various forms and should not be construed as being limited to the specific embodiments described in the present specification or application.

In accordance with some embodiments of the present disclosure, a memory device, and a method of operating the same, may prevent a voltage drop and improve the reliability of a sensing operation by dividing the start timing of a strobe operation.

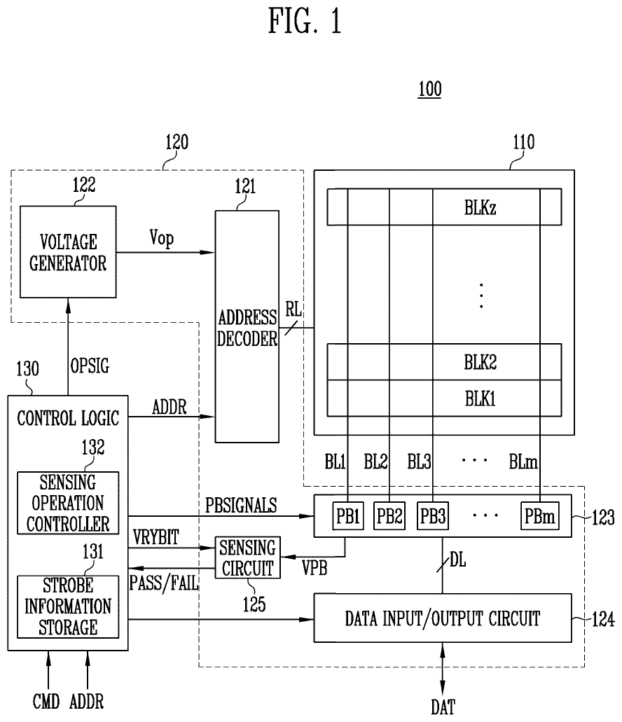

FIG. 1 is a diagram illustrating a memory device according to an embodiment.

Referring to FIG. 1, a memory device 100 may include a memory cell array 110, a peripheral circuit 120, and control logic 130. The control logic 130 may be implemented as hardware, software, or a combination of hardware and software. For example, the control logic 130 may be a control logic circuit operating in accordance with an algorithm and/or a processor executing control logic code.

The memory cell array 110 includes a plurality of memory blocks BLK1 to BLKz. The plurality of memory blocks BLK1 to BLKz are connected to an address decoder 121 through row lines RL. The plurality of memory blocks BLK1 to BLKz are connected to a read and write circuit 123 through bit lines BL1 to BLm. Each of the plurality of memory blocks BLK1 to BLKz includes a plurality of memory cells.

The peripheral circuit 120 may include the address decoder 121, a voltage generator 122, the read and write circuit 123, a data input/output circuit 124, and a sensing circuit 125. The peripheral circuit 120 drives the memory cell array 110. For example, the peripheral circuit 120 may drive the memory cell array 110 to perform a program operation, a read operation, and an erase operation.

The address decoder 121 is connected to the memory cell array 110 through the row lines RL. The row lines RL may include drain select lines, word lines, source select lines, and a common source line.

The address decoder 121 is configured to operate in response to the control of the control logic 130. The address decoder 121 receives an address ADDR from the control logic 130.

The address decoder 121 is configured to decode a block address of the received address ADDR. The address decoder 121 selects at least one memory block among the memory blocks BLK1 to BLKz according to the decoded block address. The address decoder 121 is configured to decode a row address of the received address ADDR. The address decoder 121 may select at least one word line of the selected memory block by applying voltages provided from the voltage generator 122 to at least one word line WL according to the decoded row address.

During a program operation, the address decoder 121 may apply a program voltage to a selected word line and apply a pass voltage having a level less than that of the program voltage to unselected word lines. During a program verify operation, the address decoder 121 may apply a verify voltage to the selected word line and apply a verify pass voltage having a level greater than that of the verify voltage to the unselected word lines.

During a read operation, the address decoder 121 may apply a read voltage to the selected word line and apply a read pass voltage having a level greater than that of the read voltage to the unselected word lines.

According to an embodiment of the present disclosure, the erase operation of the memory device 100 is performed in a memory block unit. The address ADDR input to the memory device 100 during an erase operation includes a block address. The address decoder 121 may decode the block address and select one memory block according to the decoded block address. During an erase operation, the address decoder 121 may apply a ground voltage to the word lines input to the selected memory block.

According to an embodiment of the present disclosure, the address decoder 121 may be configured to decode a column address of the transmitted address ADDR. The decoded column address may be transmitted to the read and write circuit 123. As an example, the address decoder 121 may include a component such as a row decoder, a column decoder, and an address buffer.

The voltage generator 122 is configured to generate a plurality of operation voltages Vop by using an external power voltage supplied to the memory device 100. The voltage generator 122 operates in response to the control of the control logic 130.

In an embodiment, the voltage generator 122 may generate an internal power voltage by regulating the external power voltage. The internal power voltage generated by the voltage generator 122 is used as the operation voltage Vop of the memory device 100.

In an embodiment, the voltage generator 122 may generate the plurality of operation voltages Vop using the external power voltage or the internal power voltage. The voltage generator 122 may be configured to generate various voltages required by the memory device 100. For example, the voltage generator 122 may generate a plurality of erase voltages, a plurality of program voltages, a plurality of pass voltages, a plurality of selection read voltages, and a plurality of non-selection read voltages.

The voltage generator 122 may include a plurality of pumping capacitors that receive the internal power voltage to generate the plurality of operation voltages Vop having various voltage levels. The voltage generator 122 may generate the plurality of operation voltages Vop by selectively activating the plurality of pumping capacitors in response to the control of the control logic 130.

The plurality of generated operation voltages Vop may be supplied to the memory cell array 110 by the address decoder 121.

The read and write circuit 123 includes a plurality of page buffers PB1 to PBm. The plurality of page buffers PB1 to PBm are connected to the memory cell array 110 through a plurality of bit lines BL1 to BLm, respectively. The plurality of page buffers PB1 to PBm operate in response to the control of the control logic 130.

The plurality of page buffers PB1 to PBm communicate data DAT with the data input/output circuit 124. At a time of programing, the plurality of page buffers PB1 to PBm receive the data DAT to be stored through the data input/output circuit 124 and data lines DL.

During a program operation, when a program voltage is applied to the selected word line, the plurality of page buffers PB1 to PBm may transmit the data DAT to be stored and received through the data input/output circuit 124 to the selected memory cells through the bit lines BL1 to BLm. The memory cells of the selected page are programmed according to the transmitted data DAT. A memory cell connected to a bit line to which a program allowable voltage (for example, a ground voltage) is applied may have an increased threshold voltage. A threshold voltage of a memory cell connected to a bit line to which a program inhibition voltage (for example, a power voltage) is applied may be maintained. During a program verify operation, the plurality of page buffers PB1 to PBm read the data DAT stored in the memory cells from the selected memory cells through the bit lines BL1 to BLm.

During a read operation, the read and write circuit 123 may read the data DAT from the memory cells of the selected page through the bit lines BL1 to BLm and store the read data DAT in the plurality of page buffers PB1 to PBm.

During an erase operation, the read and write circuit 123 may float the plurality of bit lines BL1 to BLm. In an embodiment, the read and write circuit 123 may include a column select circuit.

The data input/output circuit 124 is connected to the plurality of page buffers PB1 to PBm through the data lines DL. The data input/output circuit 124 operates in response to the control of the control logic 130.

The data input/output circuit 124 may include a plurality of input/output buffers (not shown) that receive input data DAT. During a program operation, the data input/output circuit 124 receives the data DAT to be stored from an external controller (not shown). During a read operation, the data input/output circuit 124 outputs the data DAT transmitted from the plurality of page buffers PB1 to PBm included in the read and write circuit 123 to the external controller.

During a read operation or a verify operation, the sensing circuit 125 may generate a reference current in response to a signal of an allowable bit VRYBIT generated by the control logic 130 and may compare a sensing voltage VPB received from the read and write circuit 123 with a reference voltage generated by the reference current to output a pass signal or a fail signal to the control logic 130.

The control logic 130 may be connected to the address decoder 121, the voltage generator 122, the read and write circuit 123, the data input/output circuit 124, and the sensing circuit 125. The control logic 130 may be configured to control all operations of the memory device 100. The control logic 130 may operate in response to a command CMD transmitted from an external device.

The control logic 130 may generate various signals in response to the command CMD and the address ADDR to control the peripheral circuit 120. For example, the control logic 130 may generate an operation signal OPSIG, the row address, read and write circuit control signals PBSIGNALS, and the allowable bit VRYBIT in response to the command CMD and the address ADDR. The control logic 130 may output the operation signal OPSIG to the voltage generator 122, output the row address to the address decoder 121, output the read and write circuit control signals PBSIGNALS to the read and write circuit 123, and output the allowable bit VRYBIT to the sensing circuit 125. In addition, the control logic 130 may determine whether the verify operation has passed or failed in response to the pass or fail signal PASS/FAIL output by the sensing circuit 125.

In an embodiment, the control logic 130 may include strobe information storage 131 and a sensing operation controller 132. The strobe information storage 131 may be a strobe information storage circuit or a strobe information storage device.

The plurality of page buffers PB1 to PBm included in the read and write circuit 123 may perform strobe operations of latching data stored in the plurality of memory cells.

The strobe information storage 131 may store split condition information regarding the start timing of the strobe operations. The split condition information may include a first strobe table and a second strobe table.

In an embodiment, the first strobe table may include splitting or not splitting of the start timing of the strobe operations according to a comparison result of a target expected number of latch flips and a threshold value. In an embodiment, the first strobe table may include a split number of the start timing of the strobe operations corresponding to each of a plurality of reference ranges to which the target expected number of latch flips belongs.

In an embodiment, the second strobe table may include the splitting or not splitting of the start timing of the strobe operations corresponding to each of a plurality of verify loop counts. In an embodiment, the second strobe table may include the splitting or not splitting of the start timing of the strobe operations corresponding to each of the plurality of verify loop counts for each verify level.

Based on the split condition information, the sensing operation controller 132 may control the start timing of the strobe operations according to the expected number of latch flips of a sensing latch included in each of the plurality of page buffers in the program verify operation.

The sensing operation controller 132 may control the start timing of the strobe operations based on the target expected number of latch flips corresponding to a target verify loop among a plurality of verify loops included in the program verify operation.

In an embodiment, the sensing operation controller 132 may divide the start timing of the strobe operations into at least two when the target expected number of latch flips is greater than or equal to the threshold value. The sensing operation controller 132 may set the start timing of the strobe operations to the same time when the target expected number of latch flips is less than the threshold value.

In an embodiment, the sensing operation controller 132 may control the read and write circuit 123 to perform the strobe operations according to a split number of the start timing corresponding to the reference range to which the target expected number of latch flips belongs.

The sensing operation controller 132 may control the start timing of the strobe operations based on a count of the target verify loop among the plurality of verify loops included in the program verify operation.

In an embodiment, the sensing operation controller 132 may control the read and write circuit 123 to perform the strobe operations according to the splitting or not splitting of the start timing which is determined based on the count of the target verify loop.

In an embodiment, the sensing operation controller 132 may control the read and write circuit 123 to perform the strobe operations according to the splitting or not splitting of the start timing determined based on a target verify level of the program verify operation and the count of the target verify loop.

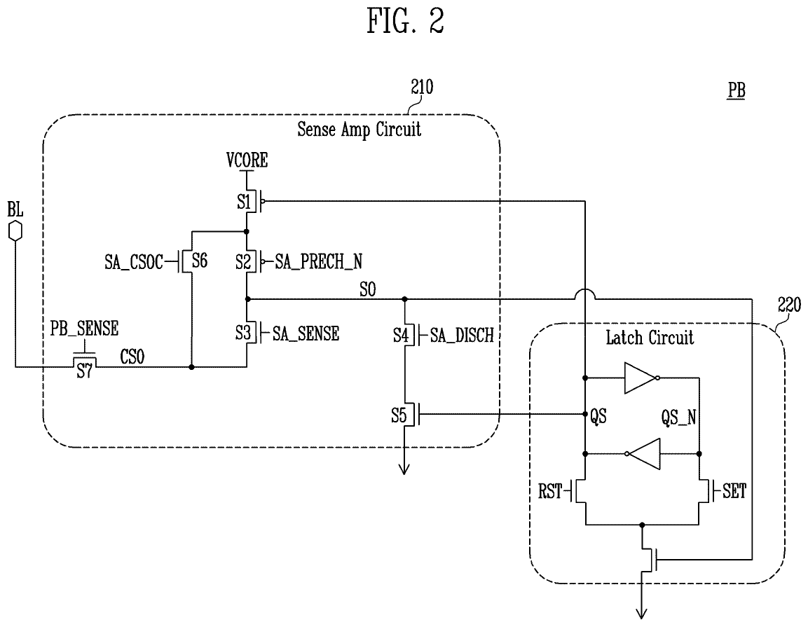

FIG. 2 is a diagram illustrating a page buffer according to an embodiment.

Referring to FIG. 2, the page buffer PB may include a sense amplifier circuit 210 and a latch circuit 220. The sense amplifier circuit 210 may connect a bit line BL and the latch circuit 220. The sense amplifier circuit 210 may perform a sensing operation of sensing data stored in a memory cell connected to the bit line BL. The latch circuit 220 may perform a strobe operation of storing program data sensed by the sense amplifier circuit 210 in the latch circuit 220.

The sense amplifier circuit 210 may include first to seventh switches S1 to S7.

The first and second switches S1 and S2 may be connected in series between a power node VCORE and a sensing node SO. The first switch S1 may be controlled according to data QS stored in the latch circuit 220. The second switch S2 may be controlled according to a sense amplifier precharge signal SA_PRECH_N. The third switch S3 may be connected between the sensing node SO and a common sensing node CSO, and may be controlled according to a sense amplifier sensing signal SA_SENSE. The fourth and fifth switches S4 and S5 may be connected in series between the sensing node SO and a ground node. The fourth switch may be controlled according to a sense amplifier discharge signal SA_DISCH. The fifth switch S5 may be controlled according to the data QS stored in the latch circuit 220. The sixth switch S6 may be connected in parallel with the second and third switches S2 and S3, and may be controlled according to a bit line precharge signal SA_CSOC. The seventh switch S7 may be connected between the bit line BL connected to the memory cell and the common sensing node CSO, and may be controlled according to a page buffer control signal PB_SENSE.

In an embodiment, an initial value of the data QS stored in the latch circuit 220 may be set to 0. In the program verify operation, when a threshold voltage of the memory cell is lower than a program verify voltage, the memory cell may be read as an on cell in which a current flows, the program verify operation may be a fail, and the data QS stored in the latch circuit 220 may be set to 0. When the threshold voltage of the memory cell is higher than the program verify voltage, the memory cell is read as an off cell in which a current does not flow, the program verify operation may be a pass, and the data QS stored in the latch circuit 220 may be set to 1.

When the program verify operation is a fail, the data QS stored in the latch circuit 220 maintains the initial value of 0, and a latch flip does not occur. When the program verify operation is a pass, a latch flip in which the data QS stored in the latch circuit 220 transitions from 0 to 1 occurs.

That is, in the program verify operation, the latch flip occurs only when the program verify operation is changed from a fail to a pass during a strobe operation of latching the data stored in the memory cell. When the latch flip occurs due to the strobe operation, a voltage drop occurs due to a short-circuit current.

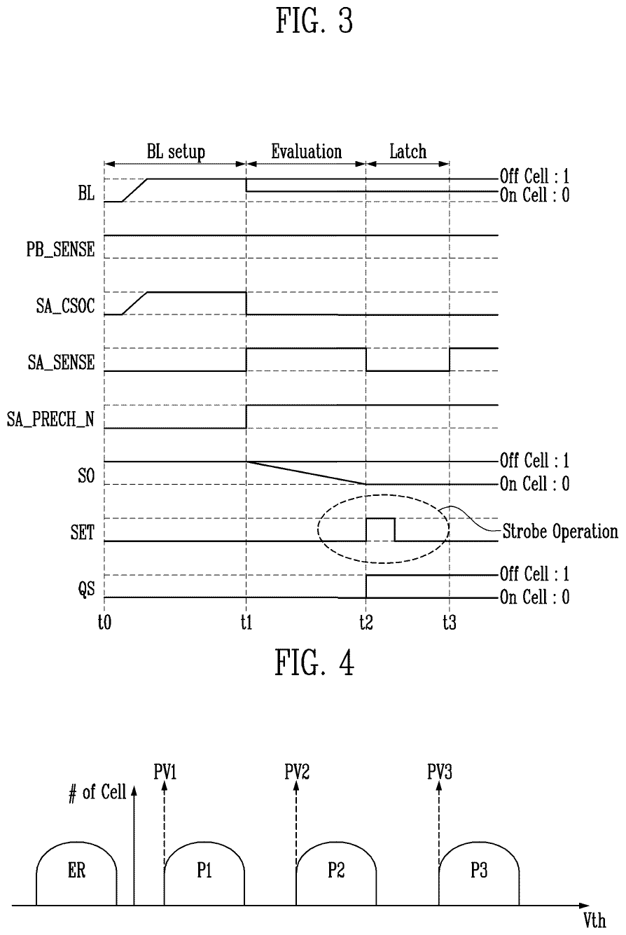

FIG. 3 is a timing diagram illustrating a sensing operation of a page buffer according to an embodiment.

Referring to FIG. 3, the sensing operation may include a bit line setup period, a sensing node evaluation period, and a data latch period.

At time to, the page buffer control signal PB_SENSE and the sense amplifier precharge signal SA_PRECH_N may be in an activation state in that NMOS switch S7 and PMOS switch S2, respectively, are closed. The sense amplifier sensing signal SA_SENSE and a set signal SET of a latch signal may be in an inactivation state in that the NMOS transistors receiving these signals at their gate are open. The data QS of the latch circuit may be initially set to 0. Referring to FIG. 2, because the first and second switches S1 and S2 are activated at to, a sensing node SO may be precharged to a power voltage level, and the data may be set to 1.

As a bit line precharge signal SA_COSC is activated in the t0 to t1 interval which is the bit line setup period, a potential of the bit line BL may be precharged to a high level.

At time t1, the bit line precharge signal SA_COSC may transit from the activation state to the inactivation state. Accordingly, the potential of the bit line BL may be maintained as the high level when the memory cell is an off cell, and may be decreased to a low level when the memory cell is an on cell.

At time t1, the sense amplifier precharge signal SA_PRECH_N may transit from the activation state to the inactivation state. The sense amplifier sensing signal SA_SENSE may transit from the inactivation state to the activation state. Accordingly, a potential of the sensing node SO may follow the potential of the bit line BL.

In the t1 to t2 time interval, which is the sensing node evaluation period, as the memory cell connected to the bit line BL is read as the off cell, the potential of the sensing node SO is maintained and the data may be set to 1. As the memory cell connected to the bit line BL is read as an on cell, the potential of the sensing node SO may be discharged and the data may be set to 0.

At time t2, the sense amplifier sensing signal SA_SENSE may transit from the activation state to the inactivation state. The set signal SET of the latch circuit may transit from the inactivation state to the activation state.

In the t2 to t3 time interval, which is the data latch period, as the set signal SET of the latch circuit is activated, data of the sensing node SO is stored as the data QS of the latch circuit. The strobe operation may be an operation in which the latch circuit stores the data of the node SO in the latch circuit in response to the set signal SET.

At time t3, the sense amplifier sensing signal SA_SENSE may transit from the inactivation state to the activation state.

FIG. 4 is a diagram illustrating a threshold voltage distribution and a verify level for each program state.

Referring to FIG. 4, it is assumed that the memory cell is a multi-level cell (MLC) that stores two data bits. The memory cell may have a threshold voltage corresponding to one of an erase state ER and first to third program states P1, P2, and P3.

A verify level corresponding to the first program state P1 may be PV1. A program verify operation of memory cells of which a threshold voltage is lower than PV1 among memory cells programmed to the first program state P1 may be considered failed. A program verify operation of memory cells of which a threshold voltage is higher than PV1 among the memory cells programmed to the first program state P1 may be considered passed.

A verify level corresponding to the second program state P2 may be PV2. A program verify operation of memory cells of which a threshold voltage is lower than PV2 among memory cells programmed to the second program state P2 may be considered failed. A program verify operation of memory cells of which a threshold voltage is higher than PV2 among the memory cells programmed to the second program state P2 may be considered passed.

A verify level corresponding to the third program state P3 may be PV3. A program verify operation of memory cells of which a threshold voltage is lower than PV3 among memory cells programmed to the third program state P3 may be considered failed. A program verify operation of memory cells of which a threshold voltage is higher than PV3 among the memory cells programmed to the third program state P3 may be considered passed.

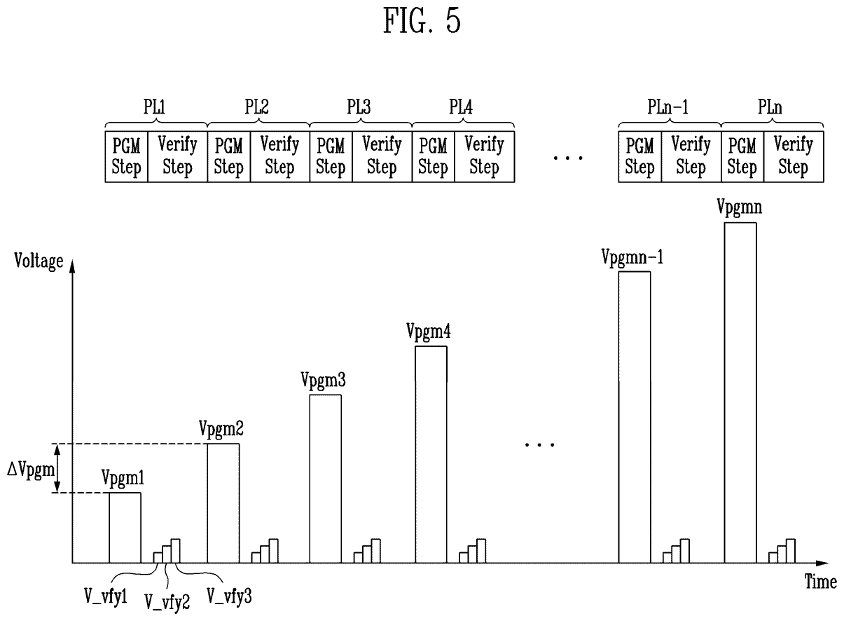

FIG. 5 is a diagram illustrating an incremental step pulse program (ISPP) operation according to an embodiment.

Referring to FIG. 5, it is assumed that the memory cell is a multi-level cell (MLC) that stores 2-bit of data. The number of data bits stored in a memory cell may be one or more.

The memory device may perform a plurality of program loops PL1 to PLn to program so that selected memory cells have a threshold voltage corresponding to one of plurality of program states P1, P2, and P3.

Each of the plurality of program loops PL1 to PLn may include a program voltage apply step PGM Step of applying a program voltage to a selected word line connected to the selected memory cells, and a program verify step Verify Step of determining whether the memory cells are programmed by applying verify voltages.

For example, when a first program loop PL1 is performed, first to third verify voltages V_vfy1 to V_vfy3 are sequentially applied to verify a program state of the selected memory cells after a first program voltage Vpgm1 is applied. At this time, memory cells of which a target program state is the first program state P1 may be verified by the first verify voltage V_vfy1. Memory cells of which a target program state is the second program state P2 may be verified by the second verify voltage V_vfy2. Memory cells of which a target program state is the third program state P3 may be verified by the third verify voltage V_vfy3.

Memory cells of which verification is passed by the respective verify voltages V_vfy1 to V_vfy3 may be determined to have a target program state, and then may be program inhibited in a second program loop PL2. In other words, a program inhibition voltage may be applied to a bit line connected to the memory cell of which verification is passed from the second program loop PL2.

A second program voltage Vpgm2 higher than the first program voltage Vpgm1 by a program step voltage ΔVpgm is applied to the selected word line to program memory cells except for the memory cells program inhibited in the second program loop PL2. Thereafter, the verify operation is performed identically to the verify operation of the first program loop PL1. Verify pass, for example, indicates that the memory cell is read as the off-cell by a corresponding verify voltage.

As described above, when the memory device programs the multi-level cell (MLC) storing 2-bits, the memory device respectively verifies memory cells setting each program state as a target program state using the first to third verify voltages V_vfy1 to V_vfy3.

During a verify operation, a verify voltage is applied to the selected word line, which is the word line to which the selected memory cells are connected. The page buffer of FIG. 2 may determine whether verification of the memory cells has passed based on a current flowing through bit lines respectively connected to the selected memory cells or a voltage applied to the bit line.

For an incremental step pulse program, because the program verify operation is performed in each program loop, a threshold voltage distribution of the memory cell may be achieved with high accuracy. A time point at which the program inhibition voltage is applied to the bit line connected to the memory cell may be determined based on a result of the program verify operation.

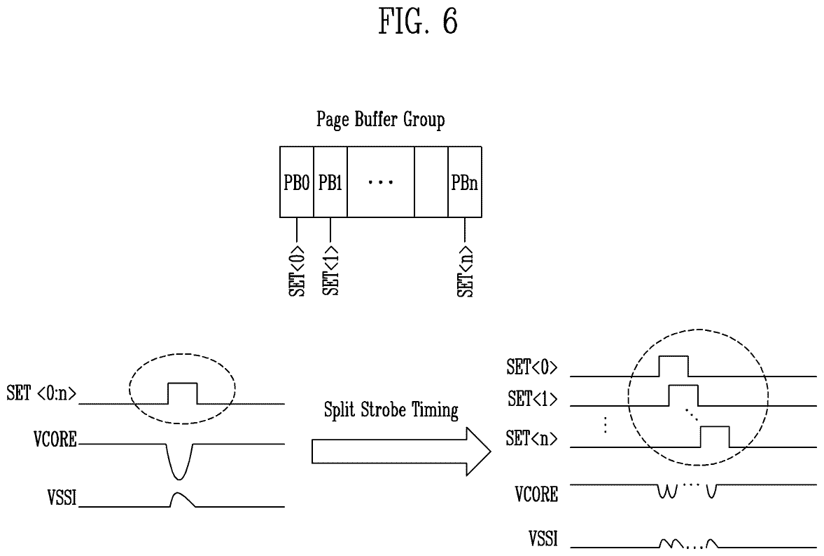

FIG. 6 is a diagram illustrating splitting of start timing of strobe operations according to an embodiment.

Referring to FIG. 6, a page buffer group may include a plurality of page buffers PB0 to PBn. A latch circuit included in each of the plurality of page buffers may perform a strobe operation of latching data stored in a memory cell in response to a corresponding set signal.

For example, a page buffer PB0 may perform a strobe operation in response to a set signal SET<0>. A page buffer PB1 may perform a strobe operation in response to a set signal SET<1>. Similarly, a page buffer PBn may perform a strobe operation in response to a set signal SET<n>.

When the strobe operations performed by the plurality of page buffers are all performed simultaneously, a sensing time may be short, but a voltage drop of a power voltage VCORE may be large. Because as the voltage drop of the power voltage VCORE is increased, a sensing variation may be increased and reliability of a sensing operation may be increased, a threshold voltage distribution of the memory cells may be deteriorated.

Conversely, when the strobe operations are performed at time intervals, the sensing time may be relatively long, but the voltage drop of the power voltage VCORE may be relatively small. Because as the voltage drop of the power voltage VCORE is decreased, the sensing variation may be decreased and reliability of the sensing operation may be increased, the threshold voltage distribution of the memory cells may be improved.

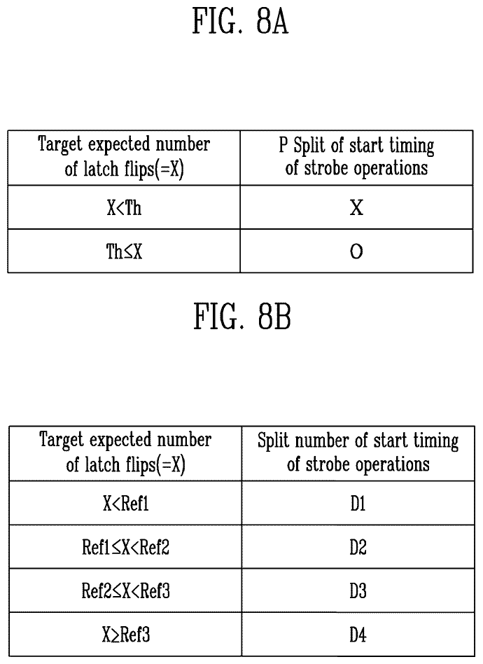

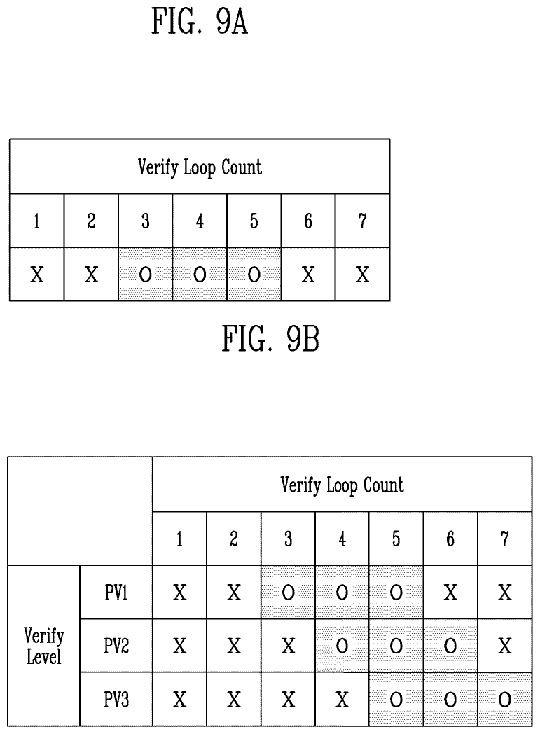

According to an embodiment of the present disclosure, a split condition regarding the start timing of the strobe operations may be determined by considering both the threshold voltage distribution and the sensing time. The split condition may include at least one of splitting or not splitting and a split number of the start timing of the strobe operations. An embodiment related to the split condition is described later with reference to FIGS. 8A, 8B, 9A, and 9B.

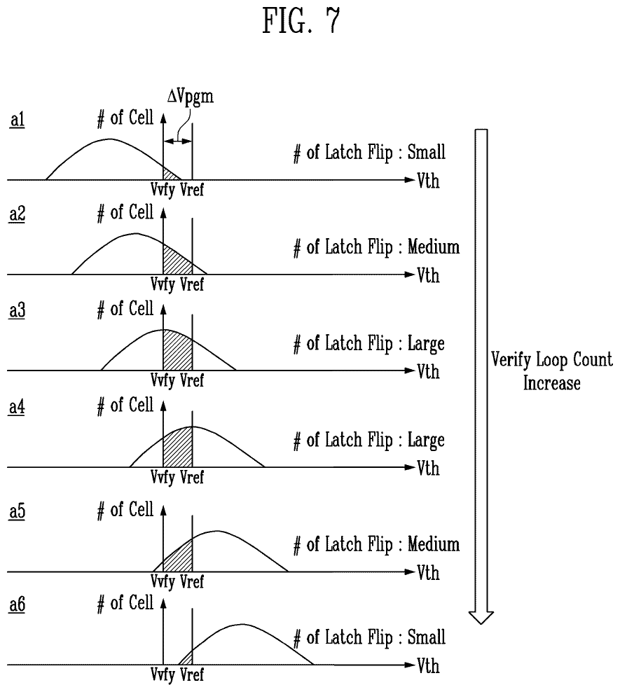

FIG. 7 is a diagram illustrating the expected number of latch flips for each count of the verify loop for a target program state.

Referring to FIG. 7, a plurality of verify loops included in the program verify operation for the target program state may be sequentially performed. In the present disclosure, because the ISPP operation described with reference to FIG. 5 is performed, whenever the verify loop count increases, the threshold voltage distribution of the memory cells may also be shifted to the right by a program step voltage ΔVpgm.

Therefore, the number of latch flips for each verify loop may be determined based on the number of memory cells belonging between a verify voltage Vvfy of the target program state and a reference voltage Vref. The reference voltage Vref may be greater than the verify voltage Vvfy by the program step voltage ΔVpgm.

The verify loop count may increase in an order of a1 to a6. Verify loop a1 may be at a time point at which a right edge of the threshold voltage distribution exceeds the verify voltage Vvfy for the first time. Verify loop a6 may be a time point at which a left edge of the threshold voltage distribution exceeds the verify voltage Vvfy for the first time. The number of latch flips corresponding to the verify loop may increase from a1 to a3. The number of latch flips corresponding to the verify loop may decrease from a4 to a6.

The expected number of latch flips corresponding to each verify loop may be a preset value. The expected number of latch flips corresponding to each verify loop may be determined based on the count of the verify loop and the verify level of the target program state.

As described with reference to FIG. 2, when a latch flip occurs, a voltage drop of the power voltage VCORE in the page buffer may occur. When the expected number of latch flips is small, a voltage drop of the power voltage VCORE is relatively small even though the start timing of the strobe operations is not split. On the other hand, when the expected number of latch flips is large and the strobe operations are performed simultaneously, a more significant voltage drop of the power voltage VCORE may occur.

According to an embodiment of the present disclosure, the expected number of latch flips corresponding to each verify loop may be different according to the count of the verify loop. Therefore, splitting, or not splitting, and a split number of the start timing of the strobe operation may be determined according to the expected number of latch flips in the verify loop.

FIG. 8A is a diagram illustrating split condition information regarding the start timing of a strobe operation according to an embodiment.

Referring to FIG. 8A, the split condition information may include splitting or not splitting of the start timing of the strobe operations according to the threshold value Th.

For example, when the target expected number of latch flips X is less than the threshold value Th, the start timing of the strobe operations might not be split, and the strobe operations may be performed simultaneously. When the target expected number of latch flips X is greater than or equal to the threshold value Th, the start timing of the strobe operations may be split into at least two. The strobe operations may be performed separately at the split start timings.

FIG. 8B is a diagram illustrating split condition information regarding the start timing of a strobe operation according to an embodiment.

Referring to FIG. 8B, the split condition information may include split numbers D1 to D4 of the start timing of the strobe operations corresponding to each of a plurality of reference ranges determined based on a plurality of reference values Ref1 to Ref3. D1 may be a positive integer greater than or equal to 0. A value of the split number may increase from D1 to D4. The number of reference ranges and the value of the split number are not limited to the present embodiment.

The split number of the start timing of the strobe operations may be determined according to the reference range to which the target expected number of latch flips X belongs in the split condition information.

For example, when the target expected number of latch flips X is less than a first reference value Ref1, the split number of the start timing may be D1. When the target expected number of latch flips X is greater than or equal to the first reference value Ref1 and less than a second reference value Ref2, the split number of the start timing may be D2. When the target expected number of latch flips X is greater than or equal to the second reference value Ref2 and less than a third reference value Ref3, the split number of the start timing may be D3. When the target expected number of latch flips X is greater than or equal to the third reference value Ref3, the split number of the start timing may be D4.

FIG. 9A is a diagram illustrating split condition information regarding the start timing of a strobe operation according to an embodiment.

Referring to FIG. 9A, the split condition information may include splitting or not splitting of the start timing of the strobe operations corresponding to each of the plurality of verify loop counts.

For example, when the count of the target verify loop is 1, 2, 6, or 7, the start timing of the strobe operations might not be split and the strobe operations may be performed simultaneously. When the count of the target verify loop is 3, 4, or 5, the start timing of the strobe operations may be split into at least two, and the strobe operations may be performed separately at the split start timings.

FIG. 9B is a diagram illustrating split condition information regarding the start timing of a strobe operation according to an embodiment.

The split condition information may include splitting or not splitting of the start timing of the strobe operations corresponding to each of the plurality of verify loop counts for each verify level.

For example, when the verify level of the program verify operation is PV1, the start timing of the strobe operations may be split into at least two only when the count of the target verify loop is 3, 4, or 5, and the strobe operations may be performed separately at the split start timings. When the verify level of the program verify operation is PV2, the start timing of the strobe operations may be split into at least two only when the count of the target verify loop is 4, 5, or 6, and the strobe operations may be performed separately at the split start timings. When the verify level of the program verify operation is PV3, the start timing of the strobe operations may be split into at least two only when the count of the target verify loop is 5, 6, or 7, and the strobe operations may be performed separately at the split start timings.

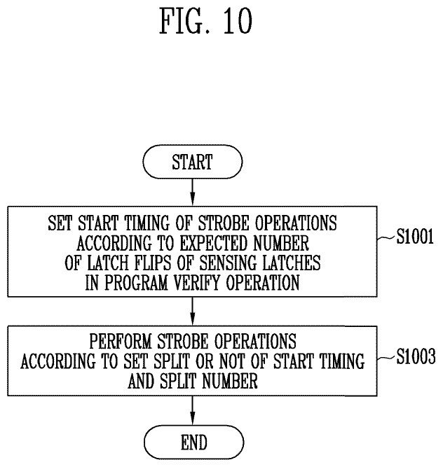

FIG. 10 is a flowchart illustrating the operation of a memory device according to an embodiment.

Referring to FIG. 10, at S1001, the memory device may set the start timing of the strobe operations according to the expected number of latch flips of the sensing latches in the program verify operation.

At S1003, the memory device may perform the strobe operations according to the set splitting or not splitting and split number of the start timing.

What is claimed is:

1. A memory device comprising:
a memory cell array including a plurality of memory cells;
a plurality of page buffers configured to perform strobe operations of latching data stored in the plurality of memory cells;
a strobe information storage configured to store split condition information regarding the start timing of the strobe operations; and
a sensing operation controller configured to control the start timing of the strobe operations according to an expected number of latch flips of a sensing latch included in each of the plurality of page buffers in a program verify operation.

2. The memory device of claim 1, wherein the sensing operation controller is configured to control the start timing of the strobe operations based on a target expected number of latch flips corresponding to a target verify loop among a plurality of verify loops included in the program verify operation.

3. The memory device of claim 2, wherein the sensing operation controller is configured to divide the start timing of the strobe operations into at least two different times when the target expected number of latch flips is greater than or equal to a threshold value.

4. The memory device of claim 2, wherein the sensing operation controller is configured to set the start timing of the strobe operations to the same time when the target expected number of latch flips is less than a threshold value.

5. The memory device of claim 2, wherein the strobe information storage is configured to store a first strobe table including a split number of the start timing of the strobe operations corresponding to each of a plurality of reference ranges, as the split condition information.

6. The memory device of claim 5, wherein the sensing operation controller is configured to control the plurality of page buffers to perform the strobe operations according to the split number of the start timing corresponding to a reference range to which the target expected number of latch flips belongs among the plurality of reference ranges.

7. The memory device of claim 1, wherein the sensing operation controller is configured to control the start timing of the strobe operations based on a count of a target verify loop among a plurality of verify loops included in the program verify operation.

8. The memory device of claim 7, wherein the strobe information storage is configured to store as the split condition information a second strobe table including an indication of whether the start timing of the strobe operations corresponding to each of a plurality of verify loop counts is split or not split.

9. The memory device of claim 8, wherein the sensing operation controller is configured to control the plurality of page buffers to perform the strobe operations according to whether the start timing is split, which is determined based on a count of the target verify loop in the second strobe table.

10. The memory device of claim 9, wherein the second strobe table includes an indication of whether there is a splitting or not of the start timing of the strobe operations corresponding to each of the plurality of verify loop counts, for each verify level, and
wherein the sensing operation controller is configured to control the plurality of page buffers to perform the strobe operations according to the splitting or not splitting of the start timing determined based on a target verify level of the program verify operation and the count of the target verify loop.

11. A method of operating a memory device including a plurality of page buffers that perform strobe operations of latching data stored in a plurality of memory cells, the method comprising:
setting the start timing of the strobe operations according to an expected number of latch flips of a sensing latch included in each of the plurality of page buffers in a program verify operation based on split condition information regarding the start timing of the strobe operations; and
performing the strobe operations according to the set start timing.

12. The method of claim 11, wherein setting the start timing comprises dividing the start timing of the strobe operations into at least two different times when a target expected number of latch flips corresponding to a target verify loop among a plurality of verify loops included in the program verify operation is greater than or equal to a threshold value, and setting the start timing of the strobe operations to the same time when the target expected number of latch flips is less than the threshold value.

13. The method of claim 11, wherein setting the start timing comprises setting a split number of the start timing based on a target expected number of latch flips corresponding to a target verify loop among a plurality of verify loops included in the program verify operation.

14. The method of claim 13, wherein a first strobe table among the split condition information includes the split number of the start timing of the strobe operations corresponding to each of a plurality of reference ranges, and
wherein the split number of the start timing is determined based on the first strobe table and the target expected number of latch flips.

15. The method of claim 11, wherein setting the start timing comprises setting splitting or not splitting of the start timing based on a count of a target verify loop among a plurality of verify loops included in the program verify operation.

16. The method of claim 15, wherein a second strobe table among the split condition information includes an indication of the splitting or not splitting of the start timing of the strobe operations corresponding to each of the plurality of verify loop counts, and
wherein the splitting or not splitting of the start timing is determined based on the second strobe table and the count of the target verify loop.

17. The method of claim 16, wherein the second strobe table includes an indication of the splitting or not splitting of the start timing of the strobe operations corresponding to each of the plurality of verify loop counts for each verify level, and
wherein the splitting or not splitting of the start timing is determined based on the second strobe table, a target verify level of the program verify operation, and the count of the target verify loop.

18. The method of claim 11, wherein performing the strobe operations comprises starting and performing at different timings the strobe operations according to the set splitting or not splitting of the start timing and a split number.
